(19) United States
(12) Patent Application Publication
(10) Pub. No.: US 2022/0173152 A1
(43) Pub. Date: Jun. 2, 2022

(54) SEMICONDUCTOR APPARATUS AND METHOD OF PRODUCING A SEMICONDUCTOR APPARATUS

(71) Applicant: SONY SEMICONDUCTOR SOLUTIONS CORPORATION, KANAGAWA (JP)

(72) Inventor: KENTARO IMAMIZU, TOKYO (JP)

(21) Appl. No.: 17/593,007

(22) PCT Filed: Mar. 12, 2020
(86) PCT No.: PCT/JP2020/010699

§ 371 Date: Sep. 3, 2021

(30) Foreign Application Priority Data
Mar. 20, 2019 (JP) 2019-052147

(51) Int. Cl. H01L 27/146

(52) U.S. Cl. CPC H01L 27/14636; H01L 29/78; H01L 27/14643; H01L 27/14614

(57) ABSTRACT

To reduce the connection resistance of a contact plug. A semiconductor apparatus includes a gate; a source region; a drain region; an interlayer insulating film; and a contact plug. The gate is disposed adjacent to a semiconductor substrate via a gate insulating film. The source region and the drain region are formed by introducing an impurity using, as a mask, the gate and a side wall insulating film disposed adjacent to a side surface of the gate. The interlayer insulating film is formed adjacent to the gate, the drain region, and the source region after the side wall insulating film is removed. The contact plug is disposed in a through hole formed in the interlayer insulating film and is disposed adjacent to at least one of the source region or the drain region.

### TECHNICAL FIELD

The present disclosure relates to a semiconductor apparatus and a method of producing a semiconductor apparatus. Specifically, the present disclosure relates to a semiconductor apparatus in which a MOS transistor is formed, and a method of producing the semiconductor apparatus.

### BACKGROUND ART

In the past, a semiconductor apparatus in which a MOS transistor is integrated, the device region of a semiconductor substrate is miniaturized, and the connection resistance with a wiring is reduced has been used. For example, a gate formed of polycrystalline silicon is disposed on the semiconductor substrate via a gate insulating film, and an impurity is introduced into the semiconductor substrate by ion implantation to form a semiconductor region having a shallow junction, which serves as an extension region. Next, a side wall insulating film is formed on the gate. This side wall insulating film can be formed by performing anisotropic etching after forming a film of a nitride or an oxide so as to cover the gate and the surface of the semiconductor substrate. Next, high-concentration ion implantation is performed using the gate and the side wall insulating film as a mask to form a drain region and a source region having deep junctions on the semiconductor substrate adjacent to the side wall insulating film. At this time, since the ion implantation is not performed on the semiconductor substrate below the side wall insulating film, the semiconductor region having a shallow junction is held to form an extension region. By using the side wall insulating film as a mask, the drain region and the source region can be formed adjacent to the extension region.

Next, a metal film formed of nickel (Ni), cobalt (Co), titanium (Ti), or the like is stacked thereon and heat treatment is performed to cause these metals to react with silicon (Si) of the semiconductor substrate and the gate, thereby forming a silicide layer. Next, by removing the unreacted metal film, a silicide layer can be selectively disposed on the drain region, the source region, and the gate. Such a method of forming a silicide layer by self-alignment is called salicide. Next, a film of an insulator is disposed thereon and a through hole reaching the silicide layer adjacent to the drain region, the source region, and the gate is formed in the film of an insulator. Next, a metal or the like is embedded in this through hole to form a contact plug. Since the silicide layer is disposed between the contact plug and the drain region, the source region, and the gate, it is possible to reduce the connection resistance between the drain region and the like and the contact plug.

As such a semiconductor apparatus, for example, a semiconductor apparatus in which a wiring formed of polycrystalline silicon is formed in a device isolation region disposed around an active region, which is a region in which devices such as a MOS transistor are formed, and silicided, has been proposed (see, for example, Patent Literature 1.). The silicide layer of the wiring of this device isolation region is formed simultaneously with the silicide layer in the above-mentioned MOS transistor.

### CITATION LIST

### Patent Literature

Patent Literature 1: Japanese Patent Application Laid-open No. 2009-094439

### DISCLOSURE OF INVENTION

### Technical Problem

The above-mentioned existing technology has a problem that the formation of a contact plug to be connected to a semiconductor region such as a drain region becomes difficult when a MOS transistor is miniaturized. Since the region in which a contact plug is to be formed is reduced and the region in which the contact plug and the semiconductor region are joined to each other is reduced with the miniaturization, it becomes difficult to form a contact plug having a low connection resistance.

The present disclosure has been made in view of the above-mentioned problem, and an object of the present disclosure is to reduce the connection resistance of the contact plug and make it easy to form the contact plug even when a MOS transistor is miniaturized.

### Solution to Problem

The present disclosure has been made to solve the above-mentioned problem, and a first aspect thereof is a semiconductor apparatus including: a gate that is disposed adjacent to a semiconductor substrate via a gate insulating film; a source region and a drain region of the semiconductor substrate, the source region and the drain region being formed by introducing an impurity using, as a mask, the gate and a side wall insulating film disposed adjacent to a side surface of the gate; an interlayer insulating film that is formed adjacent to the gate, the drain region, and the source region after the side wall insulating film is removed; and a contact plug that is disposed in a through hole formed in the interlayer insulating film and is disposed adjacent to at least one of the source region or the drain region.

Further, in this first aspect, an interval between the contact plug and the gate may be substantially twice or less a width of a bottom portion of the contact plug.

Further, in this first aspect, a bottom portion of the contact plug may have a width smaller than a thickness of the gate.

Further, in this first aspect, an interval between the contact plug and the gate may be less than or equal to the thickness of the gate.

Further, in this first aspect, the semiconductor apparatus may further include: a second source region; and a second drain region, each of the second source region and the second drain region being a region of the semiconductor substrate in a vicinity of the gate and being formed by introducing an impurity before the side wall insulating film is disposed.

Further, in this first aspect, sizes of the second source region and the second drain region may be adjusted after the side wall insulating film is removed.

Further, in this first aspect, the semiconductor apparatus may further include an electrode layer that is disposed between the contact plug and the semiconductor substrate and is formed of a compound of the semiconductor substrate and a metal.

Further, in this first aspect, the electrode layer may be disposed before the interlayer insulating film is formed.

Further, in this first aspect, the electrode layer may be disposed after the through hole is formed in the interlayer insulating film.

Further, a second aspect of the present disclosure is a method of producing a semiconductor apparatus, including: a gate forming step of disposing a gate on a semiconductor substrate via a gate insulating film; a side-wall-insulating-film disposing step of disposing a side wall insulating film adjacent to a side surface of the gate; a drain-source forming step of forming a drain region and a source region of the semiconductor substrate, the drain region and the source region being formed by introducing an impurity using, as a mask, the disposed side wall insulating film and the gate; a side-wall-insulating-film removing step of removing the disposed side wall insulating film; an interlayer-insulating-film forming step of forming an interlayer insulating film adjacent to the gate, the drain region, and the source region after the side wall insulating film is removed; and a contact-plug forming step of disposing a contact plug adjacent to at least one of the source region or the drain region, the contact plug being disposed in a through hole formed in the interlayer insulating film.

By adopting such an aspect, the effect of removing a side wall insulating film when a through hole in which a contract plug is to be disposed is formed in an interlayer insulating film is provided. The exclusion of the effect of the side wall insulating film on the formation of the through hole is assumed.

### BRIEF DESCRIPTION OF DRAWINGS

FIG. 1 is a diagram showing a configuration example of a semiconductor apparatus according to an embodiment of the present disclosure.

FIG. 2 is a diagram showing a configuration example of a semiconductor apparatus according to a first embodiment of the present disclosure.

FIG. 3 is a diagram showing an example of a method of producing a semiconductor apparatus according to the first embodiment of the present disclosure.

FIG. 4 is a diagram showing an example of the method of producing a semiconductor apparatus according to the first embodiment of the present disclosure.

FIG. 5 is a diagram showing an example of the method of producing a semiconductor apparatus according to the first embodiment of the present disclosure.

FIG. 6 is a diagram showing an example of the method of producing a semiconductor apparatus according to the first embodiment of the present disclosure.

FIG. 7 is a diagram showing an example of the method of producing a semiconductor apparatus according to the first embodiment of the present disclosure.

FIG. 8 is a diagram describing the effect of the semiconductor apparatus according to the first embodiment of the present disclosure.

FIG. 9 is a diagram showing a configuration example of a semiconductor apparatus according to a second embodiment of the present disclosure.

FIG. 10 is a diagram showing a configuration example of a semiconductor apparatus according to a third embodiment of the present disclosure.

FIG. 11 is a diagram showing an example of a method of producing a semiconductor apparatus according to the third embodiment of the present disclosure.

FIG. 12 is a diagram showing another example of the method of producing a semiconductor apparatus according to the third embodiment of the present disclosure.

FIG. 13 is a diagram showing an example of a method of producing a semiconductor apparatus according to a fourth embodiment of the present disclosure.

FIG. 14 is a diagram showing a configuration example of an image sensor to which the technology according to the present disclosure may be applied.

FIG. 15 is a diagram showing a configuration example of a pixel in the image sensor to which the technology according to the present disclosure may be applied.

FIG. 16 is a cross-sectional view showing a configuration example of a pixel circuit in the image sensor to which the technology according to the present disclosure may be applied.

FIG. 17 is a cross-sectional view showing a configuration example of a photoelectric conversion unit in the image sensor to which the technology according to the present disclosure may be applied.

FIG. 18 is a block diagram showing a schematic configuration example of a camera that is an example of an imaging apparatus to which the technology according to the present disclosure may be applied.

### MODE(S) FOR CARRYING OUT THE INVENTION

Next, embodiments for carrying out the present disclosure (hereinafter, referred to as embodiments) will be described with reference to the drawings. In the accompanying drawings, the same or similar portions will be denoted by the same or similar reference symbols. Further, the embodiments will be described in the following order.
1. First embodiment
2. Second embodiment
3. Third embodiment
4. Fourth embodiment
5. Application example to image sensor
6. Application example to camera

### 1. First Embodiment

### Configuration of Semiconductor Apparatus

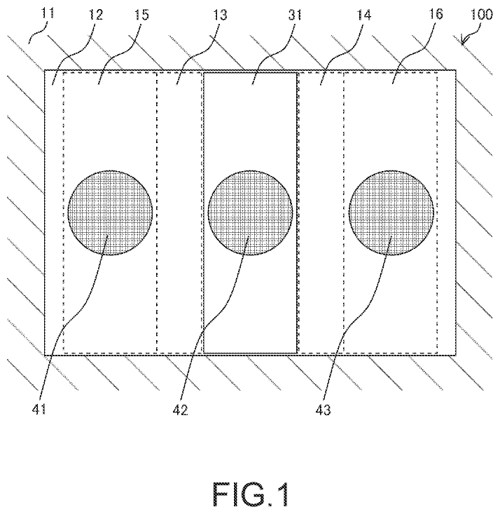

FIG. 1 is a diagram showing a configuration example of a semiconductor apparatus according to an embodiment of the present disclosure. FIG. 1 is a schematic plan view showing a configuration example of the semiconductor apparatus. Assumption is made that the semiconductor apparatus in the figure includes a MOS transistor. The semiconductor apparatus according to the present disclosure will be described taking a MOS transistor 100 in the figure as an example. FIG. 1 is a diagram showing arrangement of a semiconductor region of the MOS transistor 100 formed on a semiconductor substrate and a gate and a contact plug disposed adjacent to the surface of the semiconductor substrate.

The MOS transistor 100 is formed in a well region 12 formed on the semiconductor substrate surrounded by a device isolation region 11. Dotted rectangles in the figure each represent a semiconductor region formed in the well region 12, a solid rectangle represents a gate 31 disposed on the semiconductor substrate, and solid circles represent contact plugs 41 to 43 electrically connected to the semiconductor region. The semiconductor regions include a drain region 15, a source region 16, a second drain region 13, a second source region 14, and a channel region 19 (not shown). Details of the configuration of the MOS transistor 100 will be described below. Note that the MOS transistor 100 is an example of the semiconductor apparatus described in the claims.

### Configuration of Cross Section of Semiconductor Apparatus

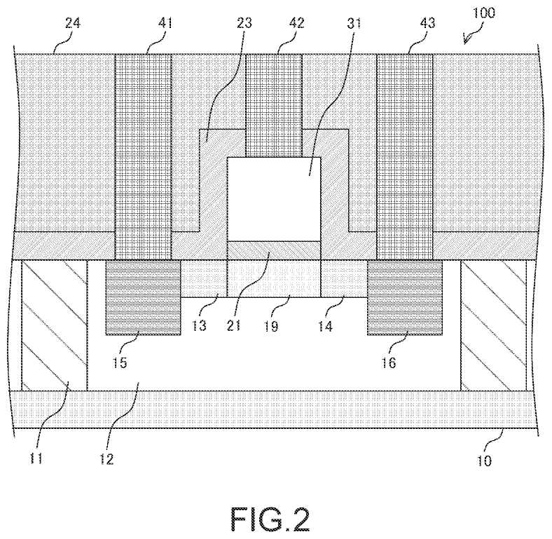

FIG. 2 is a diagram showing a configuration example of the semiconductor apparatus according to the first embodiment of the present disclosure. FIG. 2 is a cross-sectional view showing a configuration example of the MOS transistor 100 in FIG. 1. The MOS transistor 100 in the figure includes the drain region 15, the second drain region 13, the source region 16, the second source region 14, the channel region 19, the gate 31, an interlayer insulating film 24, and the contact plugs 41 to 43.

The drain region 15, the second drain region 13, the source region 16, the second source region 14, and the channel region 19 are formed in the well region 12 formed on a semiconductor substrate 10. As the semiconductor substrate 10, for example, a semiconductor substrate formed of Si can be used. The well region 12 that is a semiconductor region having a predetermined conductive type is formed on this semiconductor substrate 10. This well region 12 is formed to have a conductive type different from those of the drain region 15 and the source region 16. For example, the well region 12 may be formed of a p-type semiconductor and the drain region 15 and the source region 16 may each be formed of an n-type semiconductor. The device isolation region 11 is disposed around the well region 12. The device isolation region 11 is a region for isolating devices from another MOS transistor and the like. Assumption is made that the device isolation region 11 in the figure is formed by STI (Shallow Trench Isolation). Note that the device isolation region 11 may be formed of LOCOS (Local Oxidation of Silicon).

The drain region 15 and the source region 16 are respectively semiconductor regions corresponding to the drain and the source of the MOS transistor 100. The drain region 15 and the source region 16 are formed to have impurity concentrations higher than those of the second drain region 13 and the second source region 14 described below. This is because the contact plug 41 or the like is to be connected thereto and thus the resistance thereof needs to be reduced. Note that the drain region 15 and the source region 16 can be formed by performing ion implantation on the semiconductor substrate 10 using, as a mask, a side wall insulating film 22 disposed on a side surface of the gate 31 described below.

The channel region 19 is a region corresponding to the channel of the MOS transistor 100. This channel region 19 is formed in the well region 12 immediately below the gate 31 described below.

The second drain region 13 and the second source region 14 are respectively semiconductor regions disposed between the drain region 15 and the channel region 19 and between the source region 16 and the channel region 19. The second drain region 13 and the second source region 14 are formed to have lower impurity concentrations and shallower junctions as compared with those of the drain region 15 and the source region 16. Further, the second drain region 13 and the second source region 14 can be each formed of an n-type semiconductor having the same conductive type as those of the drain region 15 and the source region 16. By disposing the second drain region 13 and the second source region 14 adjacent to the channel region 19, it is possible to prevent the short channel effect due to miniaturization of the MOS transistor 100 from occurring. Such a second drain region 13 and such a second source region 14 are each referred to as an extension region or a lightly doped drain (LDD).

The gate 31 corresponds to the gate of the MOS transistor 100, and is disposed adjacent to the channel region 19 of the semiconductor substrate 10 via a gate insulating film 21. This gate 31 can be formed of polycrystalline silicon. Further, the gate insulating film 21 can be formed of, for example, silicon oxide (SiO₂).

Note that the side wall insulating film 22 is formed on the side surface of the gate 31. This side wall insulating film 22 is referred to as a side wall, and can be formed by disposing a film of an insulator such as an oxide and a nitride on the side surface of the gate 31 and corners of the semiconductor substrate 10. After performing ion implantation for forming the second drain region 13 and the second source region 14 in the well region 12 of the semiconductor substrate 10, the gate 31 and the side wall insulating film 22 are formed. By performing ion implantation again using the gate 31 and the side wall insulating film 22 as a mask, the drain region 15 and the source region 16 can be formed while keeping the second drain region 13 and the second source region 14. After that, the side wall insulating film 22 is removed, and the insulation film 23 and the interlayer insulating film 24 described below are deposited. For this reason, the MOS transistor 100 that has undergone the production step has a configuration in which the side wall insulating film 22 is not disposed.

The interlayer insulating film 24 is a film of an insulator disposed between the semiconductor substrate 10 and a wiring layer and is a film for insulating the surface of the semiconductor substrate 10. This interlayer insulating film 24 can be formed of, for example, SiO₂. Note that the insulation film 23 is disposed between the interlayer insulating film 24 and the semiconductor substrate 10 in the figure. This insulation film 23 is referred to as a liner insulating film, and is a film for preventing the metal used for wiring from diffusing into the semiconductor substrate 10. The insulation film 23 can be formed of, for example, silicon nitride (SiN). Further, when a through hole in which the contact plug 41 described below or the like is to be disposed is formed by etching, the insulation film 23 can be used as an etching stopper for stopping the etching.

The contact plugs 41 to 43 are each a conductive plug for electrically connecting the drain region 15 or the like and a wiring layer (not shown) to each other. The contact plugs 41 to 43 can be formed of a columnar metal. Specifically, the contact plug 41 or the like can be formed by embedding a metal such as tungsten (W) and copper (Cu) in a through hole formed in the interlayer insulating film 24 and the insulation film 23. Further, before embedding W or the like, Ti and titanium nitride (TiN) may be disposed as a base metal. The contact plug 41 is disposed adjacent to the drain region 15, the contact plug 42 is disposed adjacent to the gate 31, and the contact plug 43 is disposed adjacent to the source region 16. Note that since the above-mentioned side wall insulating film 22 is removed before disposing the insulation film 23 and the interlayer insulating film 24, a through hole can be formed without being affected by the side wall insulating film 22.

Note that the configuration of the MOS transistor 100 is not limited to this example. For example, a method other than STI and LOCOS, e.g., a method of performing the device isolation by a pn junction may be adopted. Further, a configuration in which the device isolation region 11 is omitted may be adopted.

### Method of Producing Semiconductor Apparatus

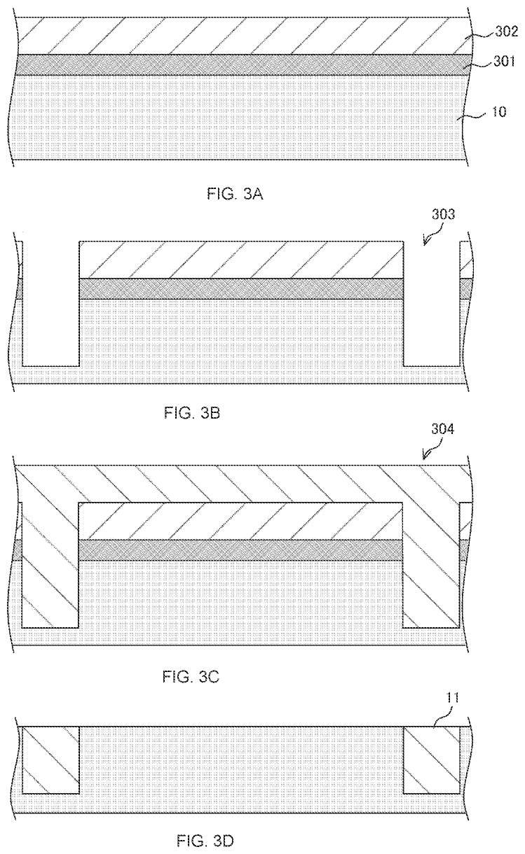

FIG. 3 to FIG. 8 are each a diagram showing an example of the method of producing a semiconductor apparatus according to the first embodiment of the present disclosure. FIG. 3 to FIG. 8 are each a diagram showing an example of the production step of the MOS transistor 100. First, a buffer oxide film 301 and a nitride film 302 are formed in the stated order on the surface of the semiconductor substrate 10. The buffer oxide film 301 can be formed by, for example, thermally oxidizing the semiconductor substrate 10. As the nitride film 302, for example, a film of SiN deposited by CVD (Chemical Vapor Deposition) can be used (Part A of FIG. 3). Next, an opening 303 having a groove shape is formed in the semiconductor substrate 10, the buffer oxide film 301, and the nitride film 302 in a region in which the device isolation region 11 is to be formed. This can be formed by the following procedure. First, a resist is disposed on the surface of the nitride film 302, and an opening is formed in the resist at a position corresponding to the opening 303. This can be performed by photolithography. Next, dry etching is performed using, as a mask, the resist in which an opening is formed, thereby forming the opening 303 (Part B of FIG. 3).

Next, an oxide film 304 formed of SiO₂ is deposited to dispose the oxide film 304 in the opening 303. This can be performed by, for example, CVD of HDP (High Density Plasma) (Part C of FIG. 3). Next, chemical mechanical polishing (CMP) is performed to grind the oxide film 304. At this time, the nitride film 302 can be used as a stopper of CMP. Next, the nitride film 302 and the oxide film 301 are removed by etching to form the device isolation region 11 (Part D of FIG. 3).

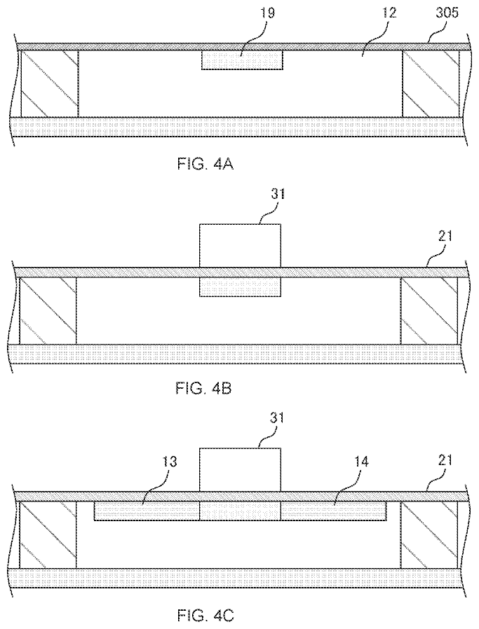

Next, a sacrificial oxide film 305 is formed on the semiconductor substrate 10. This can be formed by thermally oxidizing the surface of the semiconductor substrate 10. Next, the well region 12 and the channel region 19 are formed in the stated order. This can be performed by ion implantation (Part E of FIG. 4). After that, the sacrificial oxide film 305 is removed.

Next, the semiconductor substrate 10 is thermally oxidized to form the gate insulating film 21. Next, the gate 31 is disposed. This can be formed by staking a polycrystalline silicon film, disposing a resist having the shape of the gate 31, and performing etching (Part F of FIG. 4). This step is an example of the gate forming step described in the claims.

Next, a resist having an opening is disposed in the region in which the MOS transistor 100 is to be formed, and ion implantation is performed to form the second drain region 13 and the second source region 14. At this time, the gate 31 serves as a mask of the ion implantation, and the channel region 19 is kept (Part G of FIG. 4). Note that at this time, a halo region may be formed. The halo region is a region disposed so as to surround the extension region, and is a semiconductor region having a conductive type different from that of the extension region.

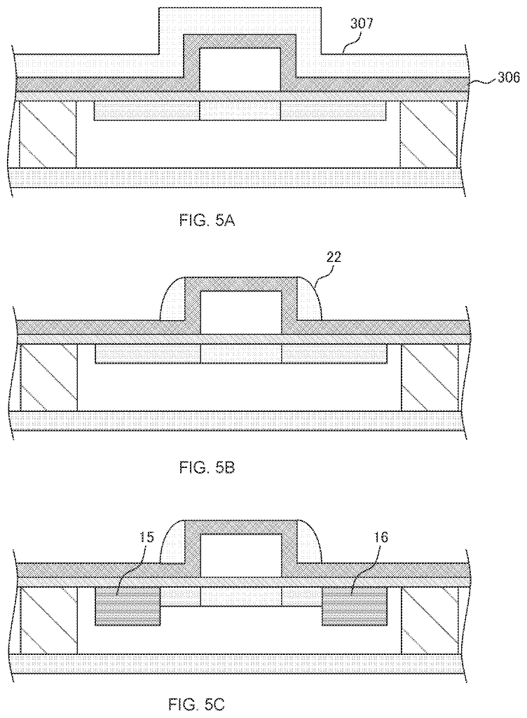

Next, side wall insulating films 306 and 307 are formed. The side wall insulating film 306 can be formed of, for example, SiN. The side wall insulating film 307 can be formed of, for example, SiO₂ (Part H of FIG. 5). Next, the side wall insulating film 307 is etched to remove the flat portion, and thus the side wall insulating film 22 is disposed on the side surface of the gate 31. This can be performed by anisotropic etching with dry etching. At this time, the etching is performed under the conditions that the etching rate of the side wall insulating film 307 is higher than that of the side wall insulating film 306. As a result, part of the side wall insulating film 307 can be left on the side surface of the gate 31 to dispose the side wall insulating film 22 (Part I of FIG. 5). This step is an example of the side-wall-insulating-film disposing step described in the claims.

Next, the drain region 15 and the source region 16 are formed. They can each be formed by disposing a resist having an opening in the region in which the MOS transistor 100 is to be formed and performing high-impurity-concentration ion implantation. At this time, the gate 31 and the side wall insulating film 22 serve as a mask, and the second drain region 13 and the second source region 14 immediately below the channel region 19 and the side wall insulating film 22 are kept (Part J of FIG. 5). This step is an example of the drain-source forming step described in the claims.

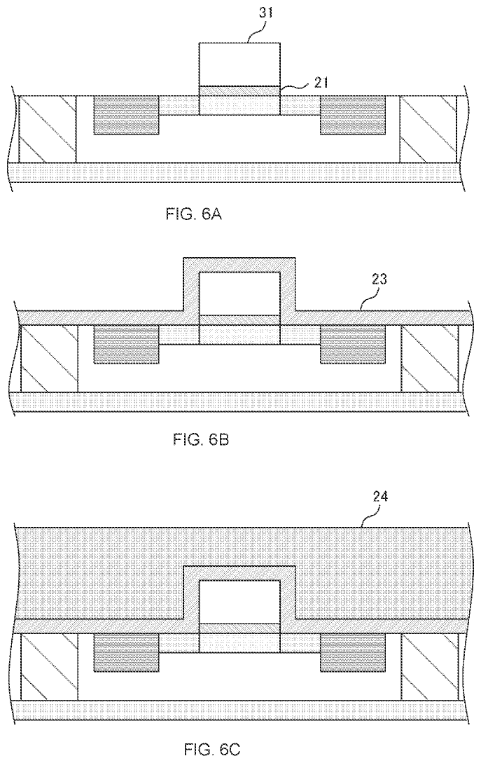

Next, the side wall insulating film 22 and the side wall insulating film 306 are removed. This can be performed by wet etching. Hydrofluoric acid is used for the etching of the side wall insulating film 22 formed of SiO₂, and hot phosphoric acid can be used for the etching of the side wall insulating film 306 formed of SiN (Part K of FIG. 6). Note that the removal of the side wall insulating film 22 may also be performed for only the specific MOS transistor 100. For example, the side wall insulating film 22 of only the MOS transistor 100 having a relatively narrow region in which the contact plug 41 is to be formed may be removed. This step is an example of the side-wall-insulating-film removing step described in the claims.

Next, the insulation film 23 is formed. This can be performed by, for example, depositing a SiN film by CVD (Part L of FIG. 6). Next, the interlayer insulating film 24 is formed. This can be performed by, for example, depositing a SiO₂ film by CVD (Part M of FIG. 6).

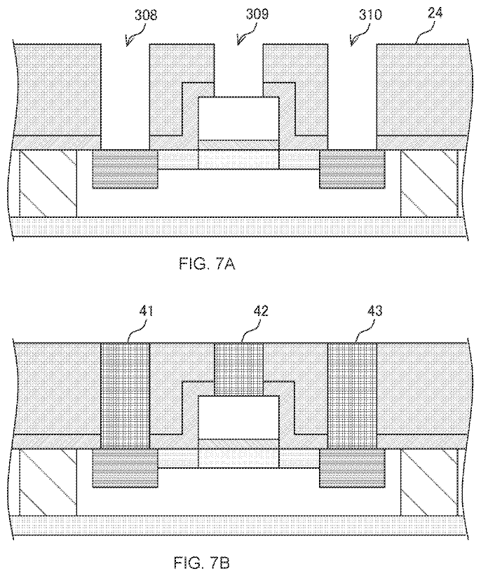

Next, through holes 308 to 310 are formed in the interlayer insulating film 24 and the insulation film 23. The through holes 308 to 310 are respectively through holes corresponding to the drain region 15, the gate 31, and the source region 16. They can be formed by the following procedure. First, resists having openings corresponding to the through holes 308 to 310 are disposed, and drying etching of the interlayer insulating film 24 is performed. At this time, since the insulation film 23 serves as an etching stopper, the through holes 308 to 310 having different depths can be simultaneously etched. Next, SiN is selectively etched to remove the insulation film 23 in the bottom portion of the corresponding through hole. As a result, the through holes 308 to 310 can be formed (Part N of FIG. 7). Next, the contact plugs 41 to 43 are respectively disposed in the through holes 308 to 310. This can be performed by, for example, forming a film of W by CVD to embed W in the through holes 308 to 310 and removing the W film other than those of the through holes 308 to 310 by CMP (Part O of FIG. 7). This step is an example of the contact-plug forming step described in the claims.

The MOS transistor 100 can be produced by the steps described above. After that, a wiring layer to be connected to the contact plugs 41 to 43, and an insulation layer for insulating the wiring layer are stacked to produce a semiconductor apparatus including the MOS transistor 100.

### Effect of Removing Side Wall Insulating Film

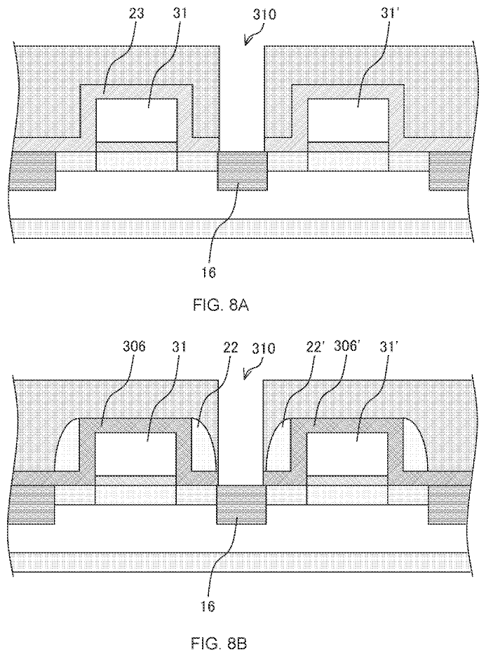

FIG. 8 is a diagram describing the effect of the semiconductor apparatus according to the first embodiment of the present disclosure. FIG. 8 is a diagram showing an example in which a through hole 310 is formed adjacent to the source region 16 in the case where two MOS transistors are connected in series. The two MOS transistors respectively include the gate 31 and a gate 31′. Part A of the figure shows an example in which the MOS transistor 100 described in FIG. 2 is applied. The through hole 310 is formed between the gate 31 and the gate 31′ from which the side wall insulating film 22 has been removed. Even in the case where the gate 31 and the gate 31′ are disposed to be close to each other, the through hole 310 can be formed without being interfered with the gates.

Meanwhile, Part B of the figure is a diagram showing an example of the case where the through hole 310 is formed between the gate 31 and the gate 31′ in which the side wall insulating film 22 and a side wall insulating film 22′, and the side wall insulating film 306 and a side wall insulating film 306′ are respectively disposed. In the MOS transistor shown in Part B of the figure, since the side wall insulating film 22 and the side wall insulating film 306 are disposed adjacent to the through hole 310, the margin at the time of forming the through hole 310 is insufficient as compared with the MOS transistor 100 shown in Part A of the figure. In the case where the through hole 310 is formed at a position contacting the side wall insulating film 22 or the like due to positional deviation when forming the through hole 310, the bottom portion of the through hole 310 is narrowed. Since the side wall insulating film 22 and the side wall insulating film 306 are used as a mask during ion implantation, these films are formed to be dense films as compared with the interlayer insulating film 24 and the insulation film 23. Further, the side wall insulating film 306 is formed to have a film thickness larger than that of the insulation film 23. For this reason, a penetrating hole is not formed at the portion of the through hole 310 contacting the side wall insulating film 22 and the side wall insulating film 306, and the portion of the through hole 310 reaching the source region 16 is narrowed.

When a contact plug is formed in such a through hole 310, the area of joining to the source region 16 is reduced and the connection resistance increases. Note that a through hole can be formed in the portion contacting the side wall insulating film 22 and the side wall insulating film 306 by prolonging the etching time. However, over-etching occurs in portions that do not contact the side wall insulating film 22 and the side wall insulating film 306.

As described above, in the semiconductor apparatus according to the first embodiment of the present disclosure, the side wall insulating film 22 is removed before forming the interlayer insulating film 24 in the MOS transistor 100. As a result, it is possible to eliminate the effect of the side wall insulating film 22 when forming, in the interlayer insulating film 24, the through hole 308 or the like in which the contact plug 41 or the like is to be disposed. It is possible to prevent the bottom portion of the through hole 308 or the like from being constricted, and form the contact plug 41 or the like having a low connection resistance.

### 2. Second Embodiment

In the MOS transistor 100 according to the above-mentioned first embodiment, the side wall insulating film 22 has been removed. Meanwhile, a semiconductor apparatus according to a second embodiment of the present disclosure is different from that in the above-mentioned first embodiment in that the size of the MOS transistor 100 from which the side wall insulating film 22 is removed is specified.

### Configuration of Cross Section of Semiconductor Apparatus

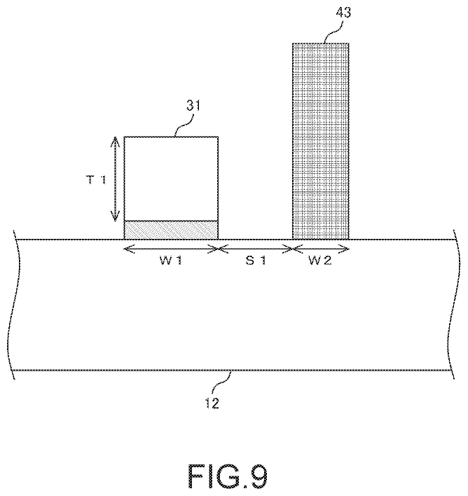

FIG. 9 is a diagram showing a configuration example of the semiconductor apparatus according to the second embodiment of the present disclosure. FIG. 9 is a diagram showing the relationship between the gate 31 and the contact plug 43. In the figure, T1 represents the thickness of the gate 31. W1 and W2 respectively represent the widths of the gate 31 and the contact plug 43. S1 represents the interval between the gate 31 and the contact plug 43. In the case where the width W2 of the contact plug 43 is substantially twice or less the interval S1 between the gate 31 and the contact plug 43, it can be determined that the gate 31 and the contact plug 43 or the like are close to each other. In this case, the side wall insulating film 22 is removed because there is a possibility that when the through hole 308 or the like is formed, it interferes with the side wall insulating film 22.

Further, in the case where the width W2 of the contact plug 43 is smaller than the thickness T1 of the gate 31, the side wall insulating film 22 may be removed. Since the size (width) of the side wall insulating film 22 is proportional to the thickness of the gate 31, it can be determined that there is a possibility that in the case where the thickness T1 of the gate 31 exceeds the width W2 of the contact plug 43, when the through hole 308 or the like is formed, it interferes with the side wall insulating film 22. Similarly, in the case where the interval S1 between the gate 31 and the contact plug 43 is less than or equal to the thickness of the gate 31, the side wall insulating film 22 can be removed. As described above, the side wall insulating film 22 can be removed in accordance with the shapes of the gate 31 and the contact plug 41 or the like and the arrangement positions thereof.

Since other configurations of the semiconductor apparatus are similar to the configurations of the semiconductor apparatus described in the first embodiment of the present disclosure, description thereof is omitted.

As described above, in the semiconductor apparatus according to the second embodiment of the present disclosure, the side wall insulating film 22 is removed in accordance with the thickness of the gate 31, the width of the gate 31 and the contact plug 41 or the like, and the interval between and the gate 31 and the contact plug 41 or the like. As a result, it is possible to remove the side wall insulating film 22 in the MOS transistor 100 that is affected by the side wall insulating film 22 when forming the through hole 308 or the like.

### 3. Third Embodiment

In the semiconductor apparatus according to the above-mentioned first embodiment, the drain region 15, the source region 16, and the gate 31 and the contact plug 41 or the like have been directly joined to each other in the MOS transistor 100. Meanwhile, a semiconductor apparatus according to a third embodiment of the present disclosure is different from that in the above-mentioned first embodiment in that a silicide layer is disposed between the drain region 15 or the like and the contact plug 41 or the like.

### Configuration of Cross Section of Semiconductor Apparatus

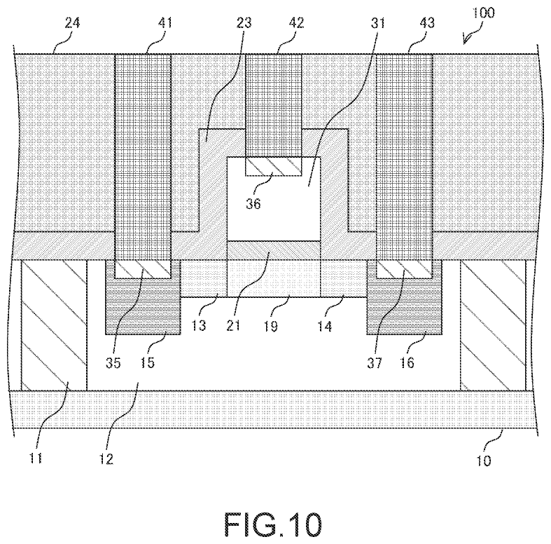

FIG. 10 is a diagram showing a configuration example of the semiconductor apparatus according to the third embodiment of the present disclosure. FIG. 10 is a cross-sectional view showing a configuration example of the MOS transistor 100, similarly to FIG. 2. The MOS transistor 100 in FIG. 10 is different from the MOS transistor 100 in FIG. 2 in that silicide layers 35 to 37 are respectively disposed in the drain region 15, the gate 31, and the source region 16.

The silicide layers 35 to 37 are each formed of a silicide metal. Here, the silicide metal is a compound of a metal and Si. Co, Ti, Ni, and the like correspond to the metal forming the silicide metal. Since the silicide metal has a low resistance, the connection resistance can be reduced by disposing the silicide metal between the gate 31, the drain region 15, or the like and the contact plug 41 or the like. The silicide layers 35 to 37 can be formed by disposing a film of Co or the like on the semiconductor region such as the drain region 15 and the surface of the gate 31 and performing heat treatment to cause Si and Co or the like to react with each other. Note that the silicide layers 35 to 37 are each an example of the electrode layer described in the claims.

### Method of Producing Semiconductor Apparatus

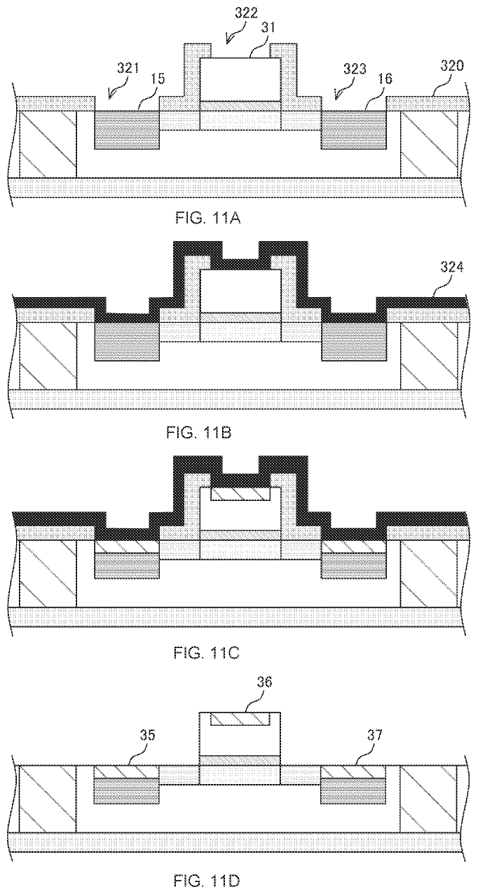

FIG. 11 is a diagram showing an example of a method of producing a semiconductor apparatus according to the third embodiment of the present disclosure. FIG. 11 is a diagram showing an example of the production step of the MOS transistor 100, and shows the step performed after the step described in Part K of FIG. 6. First, an oxide film 320 having openings 321 to 323 is formed in a region in which the silicide layers 35 to 37 are to be disposed, respectively (Part A of FIG. 11). Next, a metal film 324 formed of Co or the like is formed. This can be formed by, for example, sputtering (Part B of FIG. 11). Next, heat treatment is performed to cause the metal film 324 and Si of the drain region 15, the gate 31, and the source region 16 corresponding to the openings 321 to 323, respectively, to react with each other. As a result, a silicide metal is formed in a region in which the metal film 324 and the drain region 15 or the like are in contact with each other (Part C of FIG. 11). Next, the unreacted metal film 324 and the unreacted oxide film 320 are removed (Part D of FIG. 11). The silicide layers 35 to 37 can be formed by these steps.

After that, by performing the step of Part L of FIG. 6 and the subsequent steps, the MOS transistor 100 including the silicide layers 35 to 37 can be produced.

### Another Method of Producing Semiconductor Apparatus

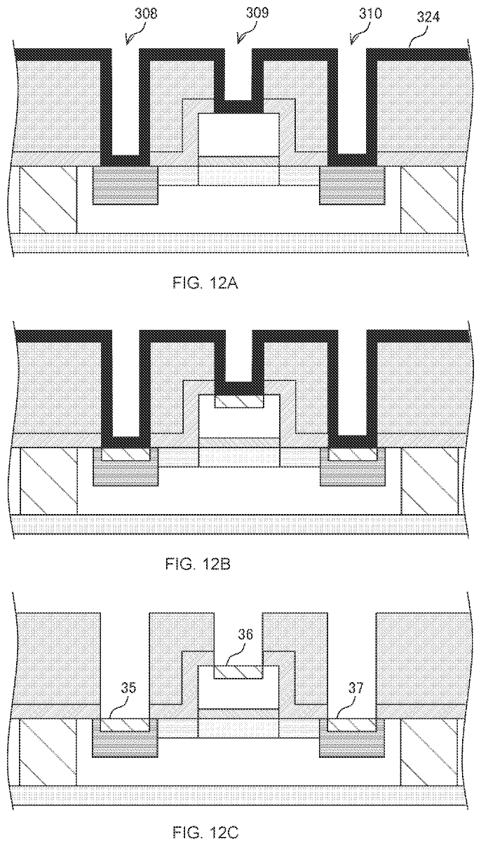

FIG. 12 is a diagram showing another example of the method of producing a semiconductor apparatus according to the third embodiment of the present disclosure. FIG. 12 is a diagram showing the production step of the silicide layers 35 to 37, which is different from that in FIG. 11, and the step performed after the step described in Part N of FIG. 7. First, the metal film 324 is formed on the surface of the interlayer insulating film 24 in which the through holes 308 to 310 have been formed. At this time, the metal film 324 is disposed also in the bottom portion of each of the through holes 308 to 310 (Part A of FIG. 12). Next, heat treatment is performed to cause the metal film 324 and Si of the drain region 15, the gate 31, and the source region 16 to react with each other, thereby forming a silicide metal (Part B of FIG. 12). Next, the unreacted metal film 324 is removed (Part C of FIG. 12). The silicide layers 35 to 37 can be formed by these steps. After that, by performing the step of Part O of FIG. 7 and the subsequent steps, the MOS transistor 100 including the silicide layers 35 to 37 can be produced.

Since other configurations of the semiconductor apparatus are similar to the configurations of the semiconductor apparatus described in the first embodiment of the present disclosure, description thereof is omitted.

As described above, in the semiconductor apparatus according to the third embodiment of the present disclosure, the silicide layers 35 to 37 are respectively disposed in the drain region 15, the gate 31, and the source region 16 in the MOS transistor 100. As a result, it is possible to reduce the connection resistance with the contact plugs 41 to 43, and reduce the loss of the MOS transistor 100.

### 4. Fourth Embodiment

In the semiconductor apparatus according to the above-mentioned first embodiment, the interlayer insulating film 24 or the like has been disposed after forming the drain region 15 and the source region 16. Meanwhile, a semiconductor apparatus according to a fourth embodiment of the present disclosure is different from that in the above-mentioned embodiment in that the sizes of the second drain region 13 and the second source region 14 are adjusted after forming the drain region 15 or the like.

### Configuration of Cross Section of Semiconductor Apparatus

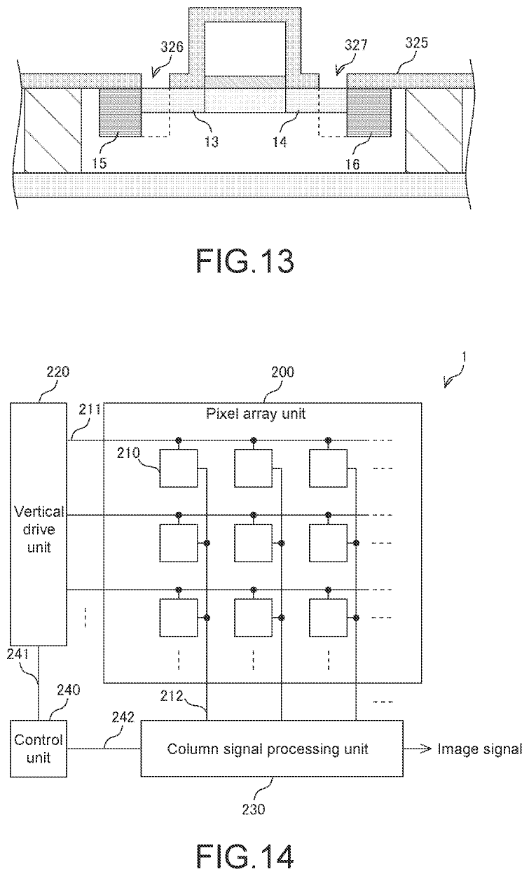

FIG. 13 is a diagram showing an example of a method of producing a semiconductor apparatus according to the fourth embodiment of the present disclosure. The production step of the MOS transistor 100 in the figure is different from the production step described in FIGS. 3 to 7 in that the sizes of the second drain region 13 and the second source region 14 are adjusted after forming the drain region 15 and the source region 16.

As described above, in the MOS transistor 100, the side wall insulating film 22 is formed after performing ion implantation of the second drain region 13 and the second source region 14, and the drain region 15 and the source region 16 are formed by performing ion implantation again. However, in the case where the width of the side wall insulating film 22 is larger than expected, the second drain region 13 and the second source region 14 are widened while the drain region 15 and the source region 16 are narrowed. In such a case, the sizes of the second drain region 13 and the second source region 14 are adjusted. This adjustment can be performed by depositing an oxide film 325 having openings 326 and 327 in a region whose size is to be adjusted, performing ion implantation, and expanding the drain region 15 and the source region 16 as shown in the figure. The dotted lines in the figure represent the drain region 15 and the source region 16 whose sizes have been adjusted. As a result, it is possible to suppress the variation in properties of the MOS transistor 100.

Since other configurations of the semiconductor apparatus are similar to the configurations of the semiconductor apparatus described in the first embodiment of the present disclosure, description thereof is omitted.

As described above, in the semiconductor apparatus according to the fourth embodiment of the present disclosure, the sizes of the second drain region 13, and the second source region 14, and the drain region 15, and the source region 16 can be adjusted even in the case where the thickness of the side wall insulating film 22 has changed. It is possible to suppress the variation in properties of the MOS transistor 100.

### 5. Application Example to Image Sensor

The technology according to the present disclosure (the present technology) is applicable to various products. For example, the present technology is applicable to an image sensor.

### Configuration of Image Sensor

FIG. 14 is a diagram showing a configuration example of an image sensor to which the technology according to the present disclosure may be applied. An image sensor 1 in the figure includes a pixel array unit 200, a vertical drive unit 220, a column signal processing unit 230, and a control unit 240.

The pixel array unit 200 is configured by arranging pixels 210 in a two-dimensional matrix pattern. Here, the pixel 210 generates an image signal corresponding to applied light. This pixel 210 includes a photoelectric conversion unit that generates charges corresponding to applied light. Further, the pixel 210 further includes a pixel circuit. This pixel circuit generates an image signal based on the charges generated by the photoelectric conversion unit. The generation of the image signal is controlled by a control signal generated by the vertical drive unit 220 described below. In the pixel array unit 200, signal lines 211 and 212 are arranged in a matrix pattern. The signal line 211 is a signal line for transmitting a control signal of the pixel circuit in the pixel 210, arranged for each row of the pixel array unit 200, and commonly wired to the pixels 210 arranged in each row. The signal line 212 is a signal line for transmitting the image signal generated by the pixel circuit of the pixel 210, arranged for each column of the pixel array unit 200, and commonly wired to the pixels 210 arranged for each column. The photoelectric conversion unit and the pixel circuit are formed on a semiconductor substrate.

The vertical drive unit 220 generates a control signal of the pixel circuit of the pixel 210. This vertical drive unit 220 transmits the generated control signal to the pixel 210 via the signal lines 211 in the figure. The column signal processing unit 230 processes the image signal generated by the pixel 210. This column signal processing unit 230 processes the image signal transmitted from the pixel 210 via the signal line 212 in the figure. For example, analog-digital conversion of converting the analog image signal generated in the pixel 210 into a digital image signal corresponds to the processing in the column signal processing unit 230. The image signal processed by the column signal processing unit 230 is output as the image signal of the image sensor 1. The control unit 240 controls the entire image sensor 1. This control unit 240 generates a control signal for controlling the vertical drive unit 220 and the column signal processing unit 230 and outputs the control signal to control the image sensor 1. The control signal generated by the control unit 240 is transmitted to the vertical drive unit 220 and the column signal processing unit 230 via the signal lines 241 and 242, respectively.

### Configuration of Pixel

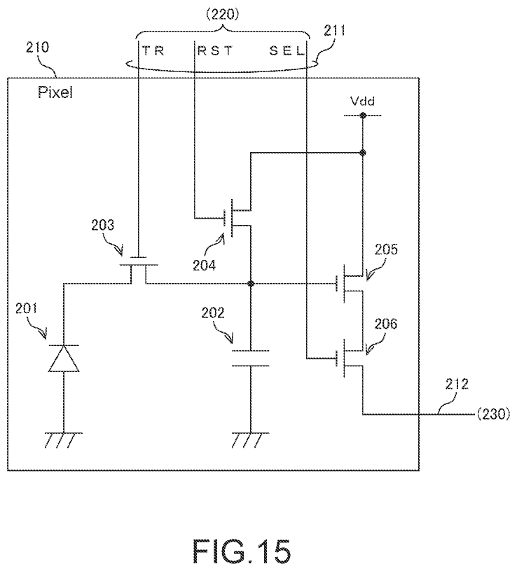

FIG. 15 is a diagram showing a configuration example of a pixel in the image sensor to which the technology according to the present disclosure may be applied. FIG. 15 is a circuit diagram showing a configuration example of the pixel 210. The pixel 210 in the figure includes a photoelectric conversion unit 201, a charge holding unit 202, and MOS transistors 203 to 206.

The anode of the photoelectric conversion unit 201 is grounded, and the cathode thereof is connected to the source of the MOS transistor 203. The drain of the MOS transistor 203 is connected to the source of the MOS transistor 204, the gate of the MOS transistor 205, and one end of the charge holding unit 202. The other end of the charge holding unit 202 is grounded. The drains of the MOS transistors 204 and 205 are commonly connected to a power supply line Vdd, and the source of the MOS transistor 205 is connected to the drain of the MOS transistor 206. The source of the MOS transistor 206 is connected to the signal line 212. The gates of the MOS transistors 203, 204, and 206 are respectively connected to a transfer signal line TR, a reset signal line RST, and a selection signal line SEL. Note that the transfer signal line TR, the reset signal line RST, and the selection signal line SEL constitute the signal lines 211.

The photoelectric conversion unit 201 generates charges corresponding to applied light as described above. As this photoelectric conversion unit 201, a photodiode can be used. Further, the charge holding unit 202 and the MOS transistors 203 to 206 constitute a pixel circuit.

The MOS transistor 203 is a transistor that transfers, to the charge holding unit 202, the charges generated by the photoelectric conversion by the photoelectric conversion unit 201. The transferring of the charges in the MOS transistor 203 is controlled by the signal transmitted via the transfer signal line TR. The charge holding unit 202 is a capacitor that holds the charges transferred by the MOS transistor 203. The MOS transistor 205 is a transistor that generates a signal based on the charges held in the charge holding unit 202. The MOS transistor 206 is a transistor that outputs, to the signal line 212, the signal generated by the MOS transistor 205 as the image signal. This MOS transistor 206 is controlled by the signal transmitted via the selection signal line SEL.

The MOS transistor 204 is a transistor that resets the charge holding unit 202 by discharging the charges heled in the charge holding unit 202 to the power supply line Vdd. This resetting by the MOS transistor 204 is controlled by the signal transmitted via the reset signal line RST, and executed before the charges are transferred by the MOS transistor 203. Note that in this resetting, also the photoelectric conversion unit 201 can be reset by conducting the MOS transistor 203. As described above, the pixel circuit converts the charges generated by the photoelectric conversion unit 201 into an image signal.

The semiconductor apparatus according to the present disclosure is applicable to each of the MOS transistors 203 to 206 in the figure. That is, the MOS transistor 100 described in FIG. 2 can be used as each of the MOS transistors 203 to 206 in the figure.

### Configuration of Pixel Circuit

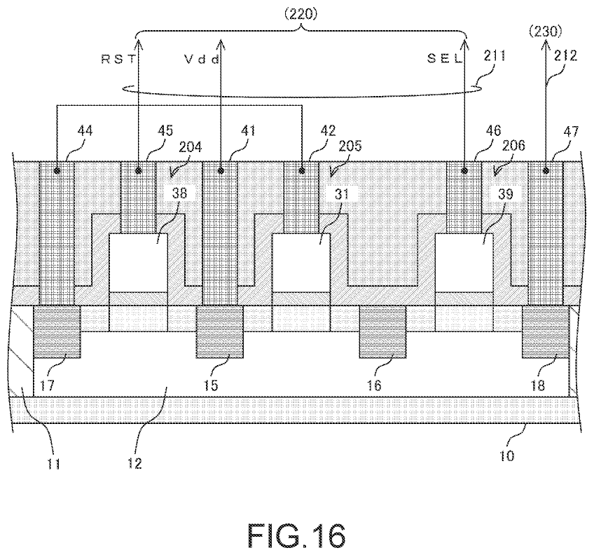

FIG. 16 is a cross-sectional view showing a configuration example of a pixel circuit in the image sensor to which the technology according to the present disclosure may be applied. FIG. 16 is a cross-sectional view showing a configuration example of the MOS transistors 204 to 206 of the pixel circuit in the pixel 210 described in FIG. 15. The semiconductor region of the MOS transistors 204 to 206 in the figure is formed in the well region 12 isolated by the device isolation region 11.

The MOS transistor 204 in the figure includes a source region 17, a gate 38, the drain region 15, and the contact plug 41 and contact plugs 44 and 45. The contact plugs 41, 44, and 45 are respectively connected to the drain region 15, the source region 17, and the gate 38. Note that the source region 17 functions also as the drain region of the MOS transistor 203 (not shown) described in FIG. 15, and corresponds to the charge holding unit 202. This charge holding unit 202 includes a floating diffusion. The MOS transistor 205 is adjacent to the MOS transistor 204. The MOS transistor 205 includes the drain region 15, the gate 31, the source region 16, and the contact plugs 41 and 42. The drain region 15 and the contact plug 41 are shared with the MOS transistor 204. The contact plug 42 is connected to the gate 31. Note that the contact plug of the source region 16 is omitted.

The MOS transistor 206 is disposed adjacent to the MOS transistor 205. The MOS transistor 206 includes the drain region (source region 16 of the MOS transistor), a gate 39, a source region 18, and contact plugs 46 and 47. Note that the source region 16 of the MOS transistor 205 serves also as the drain region of the MOS transistor 206, and is formed in the common semiconductor region. The contact plugs 46 and 47 are respectively connected to the gate 39 and the source region 18.

The contact plugs 44 and 42 are connected to each other via a wiring (not shown). Similarly, the contact plugs 45, 41, and 46 are connected to the reset signal line RST, the power supply line Vdd, and the selection signal line SEL of the signal line 211, and the contact plug 47 is connected to the signal line 212. As described above, even in the case where MOS transistors are disposed close to each other and the semiconductor region in which the contact plug 41 or the like is to be disposed is narrow, the contact plug 41, 44, and 47 can be formed while ensuring the margin by removing the side wall insulating film 22.

Since other configurations of the semiconductor apparatus are similar to the configurations of the semiconductor apparatus described in the first embodiment of the present disclosure, description thereof is omitted.

As described above, by applying the semiconductor apparatus according to the present disclosure to the image sensor 1, it is possible to reduce the connection resistance of the contact plugs 41, 44, and 47 even in the case where MOS transistors are disposed close to each other. It is possible to improve the degree of integration while preventing the performance of the MOS transistor of the image sensor 1 from deteriorating.

### Configuration Example of Photoelectric Conversion Unit

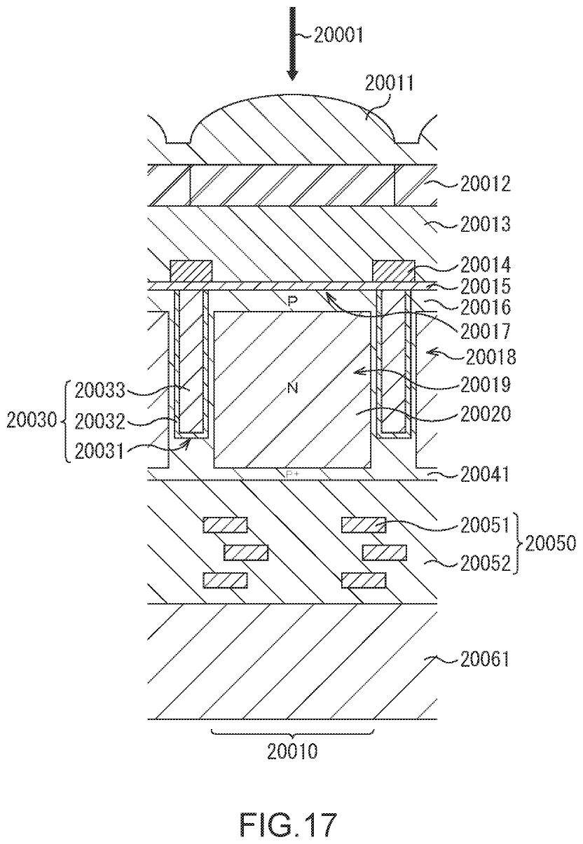

FIG. 17 is a cross-sectional view showing a configuration example of a photoelectric conversion unit in the image sensor to which the technology according to the present disclosure may be applied.

In a solid-state imaging apparatus in the figure, a PD (photodiode) 20019 receives an incident light 20001 that enters from the back surface (upper surface in the figure) side of a semiconductor substrate 20018. A flattening film 20013, a CF (color filter) 20012, and a microlens 20011 are provided above the PD 20019, and the incident light 20001 that has entered sequentially via the respective portions is received by a light-receiving surface 20017 to perform photoelectric conversion.

For example, in the PD 20019, an n-type semiconductor region 20020 is formed in a charge accumulation region for accumulating charges (electrons). In the PD 20019, the n-type semiconductor region 20020 is provided inside p-type semiconductor regions 20016 and 20041 of the semiconductor substrate 20018. The p-type semiconductor region 20041 having the impurity concentration higher than that on the back surface (upper surface) side is provided on the front surface (lower surface) side of the semiconductor substrate 20018 of the n-type semiconductor region 20020. That is, the PD 20019 has a HAD (Hole-Accumulation Diode) structure, and the p-type semiconductor regions 20016 and 20041 are formed such that dark current is prevented from occurring on the interfaces on the upper surface side and the lower surface side of the n-type semiconductor region 20020.

A pixel separation unit 20030 that electrically separates a plurality of pixels 20010 is provided inside the semiconductor substrate 20018, and the PD 20019 is provided in a region partitioned by the pixel separation unit 20030. In the case where the solid-state imaging apparatus is viewed from the upper surface side in the figure, the pixel separation unit 20030 is formed in a grid pattern so as to intervene between the plurality of pixels 20010, for example, and the PD 20019 is formed in the region partitioned by this pixel separation unit 20030.

The anode of each PD 20019 is grounded. In the solid-state imaging apparatus, the signal charges (e.g., electrons) accumulated in the PD 20019 are read via a transfer transistor (not shown) (the MOS transistor 203 in FIG. 15) or the like, and output to the vertical signal line (not shown) (the signal line 212 in FIG. 15) as an electrical signal.

A wiring layer 20050 is provided on the front surface (lower surface) opposite to the back surface (upper surface) on which the respective portions such as a light-shielding film 20014, the CF 20012, and the microlens 20011 are provided, of the semiconductor substrate 20018.

The wiring layer 20050 includes a wiring 20051 and an insulation layer 20052, and is formed such that the wiring 20051 is electrically connected to the respective devices in the insulation layer 20052. The wiring layer 20050 is a so-called multilayer wiring layer, and the interlayer insulating film constituting the insulation layer 20052 and the wiring 20051 are alternately stacked to form the wiring layer 20050. Here, as the wiring 20051, respective wirings such as a wiring to the transistor for reading charges from the PD 20019 such as a transfer transistor are stacked via the insulation layer 20052.

A support substrate 20061 is provided on the surface on the side opposite to the side on which the PD 20019 is provided, of the wiring layer 20050. For example, a substrate formed of a silicon semiconductor having the thickness of several hundred pm is provided as the support substrate 20061.

The light-shielding film 20014 is provided on the side of the back surface (upper surface in the figure) of the semiconductor substrate 20018.

The light-shielding film 20014 is configured to shield part of the incident light 20001 traveling from above the semiconductor substrate 20018 to the back surface of the semiconductor substrate 20018.

The light-shielding film 20014 is provided above the pixel separation unit 20030 provided inside the semiconductor substrate 20018. Here, the light-shielding film 20014 is provided on the back surface (upper surface) of the semiconductor substrate 20018 so as to protrude into a projecting shape via an insulation film 20015 such as a silicon oxide film. Meanwhile, the light-shielding film 20014 is not provided and is opened above the PD 20019 provided inside the semiconductor substrate 20018 such that the incident light 20001 enters the PD 20019.

That is, in the case where the solid-state imaging apparatus is viewed from the upper surface side in the figure, the plane shape of the light-shielding film 20014 is a grid pattern and an opening through which the incident light 20001 passes toward the light-receiving surface 20017 is formed.

The light-shielding film 20014 is formed of a light-shielding material that shields light. For example, the light-shielding film 20014 is formed by sequentially stacking a titanium (Ti) film and a tungsten (W) film. Alternatively, the light-shielding film 20014 can be formed by, for example, sequentially stacking a titanium nitride (TiN) film and a tungsten (W) film.

The light-shielding film 20014 is covered by the flattening film 20013. The flattening film 20013 is formed of an insulating material that causes light to be transmitted therethrough.

The pixel separation unit 20030 includes a groove portion 20031, a fixed charge film 20032, and an insulation film 20033.

The fixed charge film 20032 is formed on the side of the back surface (upper surface) of the semiconductor substrate 20018 so as to cover the groove portion 20031 that partitions the plurality of pixels 20010.

Specifically, the fixed charge film 20032 is provided so as to cover, with a certain thickness, the surface inside the groove portion 20031 formed on the back surface (upper surface) side of the semiconductor substrate 20018. Then, the insulation film 20033 is provided (deposited) so as to embed the inside of the groove portion 20031 covered by the fixed charge film 20032.

Here, the fixed charge film 20032 is formed using a high dielectric having negative fixed charges such that a positive charge (hole) accumulating region is formed on the interface portion between the fixed charge film 20032 and the semiconductor substrate 20018 to prevent dark current from occurring. When the fixed charge film 20032 is formed to have negative fixed charges, the negative fixed charges apply an electric field to the interface between the fixed charge film 20032 and the semiconductor substrate 20018, thereby forming, a positive charge (hole) accumulating region.

The fixed charge film 20032 can be formed of, for example, a hafnium oxide film (HfO₂ film). In addition, the fixed charge film 20032 may be formed to contain, for example, at least one of oxides of hafnium, zirconium, aluminum, tantalum, titanium, magnesium, yttrium, a lanthanoid element, and the like.

This PD 20019 can be used as the photoelectric conversion unit 201 of the pixel 210 described in FIG. 15.

### 6. Application Example to Camera

The technology according to the present disclosure (the present technology) is applicable to various products. For example, the present technology may be realized as an image sensor mounted on an imaging apparatus such as a camera.

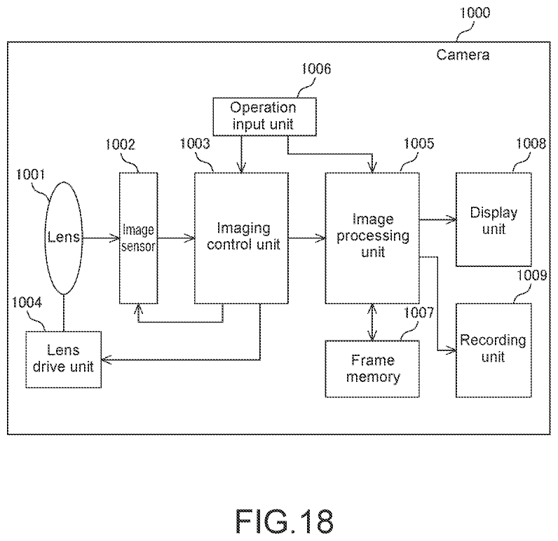

FIG. 18 is a block diagram showing a schematic configuration example of a camera that is an example of an imaging apparatus to which the technology according to the present disclosure may be applied. A camera 1000 includes a lens 1001, an image sensor 1002, an imaging control unit 1003, a lens drive unit 1004, an image processing unit 1005, an operation input unit 1006, a frame memory 1007, a display unit 1008, and a recording unit 1009.

The lens 1001 is an imaging lens of the camera 1000. This lens 1001 collects light from a subject, and causes the collected light to enter the image sensor 1002 described below to form an image of the subject.

The image sensor 1002 is a semiconductor device that images the light from the subject that is collected by the lens 1001. This image sensor 1002 generates an analog image signal corresponding to the applied light, and converts the analog image signal into a digital image signal to output the digital image signal.

The imaging control unit 1003 controls imaging performed by the image sensor 1002. This imaging control unit 1003 performs control of the image sensor 1002 by generating a control signal and outputting the control signal to the image sensor 1002. Further, the imaging control unit 1003 is capable of performing autofocusing in the camera 1000 on the basis of the image signal output from the image sensor 1002. Here, the autofocusing is a system that detects a focal position of the lens 1001 and automatically adjusts the focal position. It is possible to use, as the autofocusing, a method of detecting a focal position by detecting an image-plane phase difference using a phase difference pixel disposed in the image sensor 1002 (image-plane-phase-difference autofocusing). Further, it is also possible to apply a method (contrast autofocusing) that includes detecting, as the focal position, a position in which an image exhibits a highest contrast. The imaging control unit 1003 adjusts the position of the lens 1001 via the lens drive unit 1004 on the basis of the detected focal position, and performs autofocusing. Note that the imaging control unit 1003 can include, for example, a digital signal processor (DSP) on which firmware is mounted.

The lens drive unit 1004 drives the lens 1001 on the basis of control performed by the imaging control unit 1003. This lens drive unit 1004 is capable of driving the lens 1001 by changing the position of the lens 1001 using a built-in motor.

The image processing unit 1005 processes the image signal generated by the image sensor 1002. Demosaicking for generating an image signal of an insufficient color among image signals corresponding to red, green, and blue for each pixel, noise reduction for removing noise from an image signal, encoding of an image signal, and the like correspond to this processing. The image processing unit 1005 can include, for example, a microcomputer on which firmware is mounted.

The operation input unit 1006 receives an operation input from a user of the camera 1000. As this operation input unit 1006, for example, a push button or a touch panel can be used. An operation input received by the operation input unit 1006 is transmitted to the imaging control unit 1003 and the image processing unit 1005. After that, the processing corresponding to the operation input, e.g., processing such as imaging a subject is started.

The frame memory 1007 is a memory that stores therein a frame that is an image signal for a single screen. This frame memory 1007 is controlled by the image processing unit 1005, and holds a frame in the process of image processing.

The display unit 1008 displays thereon an image processed by the image processing unit 1005. As this display unit 1008, for example, a liquid crystal panel can be used.

The recording unit 1009 records therein an image processed by the image processing unit 1005. As this recording unit 1009, for example, a memory card or a hard disk can be used.

A camera to which the present disclosure can be applied has been described above. The present technology can be applied to the image sensor 1002 of the configurations described above. Specifically, the image sensor 1 described in FIG. 14 is applicable to the image sensor 1002.

Note that although a camera has been described as an example here, the technology according to the present disclosure may be applied to, for example, a monitoring apparatus. Further, the present disclosure can be applied to a semiconductor apparatus in the form of semiconductor module in addition to an electronic apparatus such as a camera. Specifically, the technology according to the present disclosure can be applied to an imaging module that is a semiconductor module in which the image sensor 1002 and the imaging control unit 1003 in FIG. 19 are enclosed in one package.

Finally, the description of the above-mentioned embodiments is an example of the present disclosure, and the present disclosure is not limited to the above-mentioned embodiments. Therefore, it goes without saying that various modifications can be made depending on the design and the like without departing from the technical idea according to the present disclosure even in the case of an embodiment other than the above-mentioned embodiments.

Further, the drawings in the above-mentioned embodiments are schematic, and the ratio of the dimensions of the respective units and the like do not necessarily coincide with real ones. Further, it goes without saying that the drawings have different dimensional relationships and different ratios of dimensions with respect to the same portion.

It should be noted that the present technology may take the following configurations.

(1) A semiconductor apparatus, including:

a gate that is disposed adjacent to a semiconductor substrate via a gate insulating film;

a source region and a drain region of the semiconductor substrate, the source region and the drain region being formed by introducing an impurity using, as a mask, the gate and a side wall insulating film disposed adjacent to a side surface of the gate;

an interlayer insulating film that is formed adjacent to the gate, the drain region, and the source region after the side wall insulating film is removed; and

a contact plug that is disposed in a through hole formed in the interlayer insulating film and is disposed adjacent to at least one of the source region or the drain region.

(2) The semiconductor apparatus according to (1) above, in which

an interval between the contact plug and the gate is substantially twice or less a width of a bottom portion of the contact plug.

(3) The semiconductor apparatus according to (1) above, in which

a bottom portion of the contact plug has a width smaller than a thickness of the gate.

(4) The semiconductor apparatus according to (1) above, in which

an interval between the contact plug and the gate is less than or equal to the thickness of the gate.

(5) The semiconductor apparatus according to any one of (1) to (4) above, further including:

a second source region; and

a second drain region, each of the second source region and the second drain region being a region of the semiconductor substrate in a vicinity of the gate and being formed by introducing an impurity before the side wall insulating film is disposed.

(6) The semiconductor apparatus according to (5) above, in which

sizes of the second source region and the second drain region are adjusted after the side wall insulating film is removed.

(7) The semiconductor apparatus according to any one of (1) to (6) above, further including

an electrode layer that is disposed between the contact plug and the semiconductor substrate and is formed of a compound of the semiconductor substrate and a metal.

(8) The semiconductor apparatus according to (7) above, in which

the electrode layer is disposed before the interlayer insulating film is formed.

(9) The semiconductor apparatus according to (7) above, in which

the electrode layer is disposed after the through hole is formed in the interlayer insulating film.

(10) A method of producing a semiconductor apparatus, including:

a gate forming step of disposing a gate on a semiconductor substrate via a gate insulating film;

a side-wall-insulating-film disposing step of disposing a side wall insulating film adjacent to a side surface of the gate;

a drain-source forming step of forming a drain region and a source region of the semiconductor substrate, the drain region and the source region being formed by introducing an impurity using, as a mask, the disposed side wall insulating film and the gate;

a side-wall-insulating-film removing step of removing the disposed side wall insulating film;

an interlayer-insulating-film forming step of forming an interlayer insulating film adjacent to the gate, the drain region, and the source region after the side wall insulating film is removed; and

a contact-plug forming step of disposing a contact plug adjacent to at least one of the source region or the drain region, the contact plug being disposed in a through hole formed in the interlayer insulating film.

### REFERENCE SIGNS LIST

1 image sensor
10 semiconductor substrate
11 device isolation region
12 well region
13 second drain region
14 second source region
15 drain region
16 to 18 source region
19 channel region
21 gate insulating film
22 side wall insulating film
23 insulation film
24 interlayer insulating film
31, 31′, 38, 39 gate
35 to 37 silicide layer
41 to 47 contact plug
100, 203 to 206 MOS transistor
200 pixel array unit
210 pixel
306 side wall insulating film
308 to 310 through hole

1. A semiconductor apparatus, comprising:
a gate that is disposed adjacent to a semiconductor substrate via a gate insulating film;
a source region and a drain region of the semiconductor substrate, the source region and the drain region being formed by introducing an impurity using, as a mask, the gate and a side wall insulating film disposed adjacent to a side surface of the gate;
an interlayer insulating film that is formed adjacent to the gate, the drain region, and the source region after the side wall insulating film is removed; and
a contact plug that is disposed in a through hole formed in the interlayer insulating film and is disposed adjacent to at least one of the source region or the drain region.

2. The semiconductor apparatus according to claim 1, wherein an interval between the contact plug and the gate is substantially twice or less a width of a bottom portion of the contact plug.

3. The semiconductor apparatus according to claim 1, wherein a bottom portion of the contact plug has a width smaller than a thickness of the gate.

4. The semiconductor apparatus according to claim 1, wherein an interval between the contact plug and the gate is less than or equal to the thickness of the gate.

5. The semiconductor apparatus according to claim 1, further comprising:
a second source region; and
a second drain region, each of the second source region and the second drain region being a region of the semiconductor substrate in a vicinity of the gate and being formed by introducing an impurity before the side wall insulating film is disposed.

6. The semiconductor apparatus according to claim 5, wherein
sizes of the second source region and the second drain region are adjusted after the side wall insulating film is removed.

7. The semiconductor apparatus according to claim 1, further comprising
an electrode layer that is disposed between the contact plug and the semiconductor substrate and is formed of a compound of the semiconductor substrate and a metal.

8. The semiconductor apparatus according to claim 7, wherein
the electrode layer is disposed before the interlayer insulating film is formed.

9. The semiconductor apparatus according to claim 7, wherein
the electrode layer is disposed after the through hole is formed in the interlayer insulating film.

10. A method of producing a semiconductor apparatus, comprising:
a gate forming step of disposing a gate on a semiconductor substrate via a gate insulating film;
a side-wall-insulating-film disposing step of disposing a side wall insulating film adjacent to a side surface of the gate;
a drain-source forming step of forming a drain region and a source region of the semiconductor substrate, the drain region and the source region being formed by introducing an impurity using, as a mask, the disposed side wall insulating film and the gate;
a side-wall-insulating-film removing step of removing the disposed side wall insulating film;
an interlayer-insulating-film forming step of forming an interlayer insulating film adjacent to the gate, the drain region, and the source region after the side wall insulating film is removed; and
a contact-plug forming step of disposing a contact plug adjacent to at least one of the source region or the drain region, the contact plug being disposed in a through hole formed in the interlayer insulating film.
